(19) United States
(12) Patent Application Publication
(10) Pub. No.: US 2012/0138946 A1
(43) Pub. Date: Jun. 7, 2012

(54) SEMICONDUCTOR DEVICE AND METHOD OF MANUFACTURING THE SAME

(75) Inventors: Masao Kikuchi, Tokyo (JP); Osamu Usui, Tokyo (JP)

(73) Assignee: MITSUBISHI ELECTRIC CORPORATION, Tokyo (JP)

(21) Appl. No.: 13/184,717

(22) Filed: Jul. 18, 2011

(30) Foreign Application Priority Data
Dec. 3, 2010 (JP) 2010-269982

(51) Int. Cl. H01L 23/34; H01L 21/50

(52) U.S. Cl. 257/76; 438/122; 257/E23.08; 257/E21.499

(57) ABSTRACT

A semiconductor device includes a cooler having a main surface constructed of a metal base, joined layers fixed on the metal base through joining layers, insulating layers fixed on the joined layers and which contain an organic resin as a base material, metal layers provided on the insulating layers, and semiconductor elements provided on the metal layers. A stacked structure with the joined layers, the insulating layers, and the metal layers is divided into parts containing one or the plurality of semiconductor elements, and is fixed through the joining layers on the metal base.

### BACKGROUND OF THE INVENTION

1. Field of the Invention

The present invention relates to a semiconductor device with means for cooling a semiconductor element.

2. Description of the Background Art

The conventional structure of a semiconductor device is such that metal plates are stuck on upper and lower sides of an insulating plate made of ceramic, one of the metal plates is secured by soldering on a metal base, and an element is placed on the other one of the metal plates (see patent literature 1: Japanese Patent Application Laid-Open No. 2003-204021). Further, the metal base is secured on a surface of a cooler for example by the following way mainly employed: grease is interposed between the metal base and the cooler, and then the metal base and the cooler are fastened to each other with a screw.

In order to enhance heat dissipation characteristics, an insulating layer may be stuck directly on a surface of a cooler to eliminate the need of grease of poor heat conductivity. An insulating plate made of ceramic may be stuck by brazing to a cooler (heat sink) so that an insulating layer can be directly attached to the cooler.

The structure of a semiconductor device may also be such that a circuit part in which a semiconductor element is placed and a cooler (heat dissipating fin) are electrically isolated by an insulating resin sheet (see Japanese Patent Application Laid-Open No. 11-204700 (1999)).

The semiconductor device disclosed in patent literature 1 allows the insulating layer and the cooler constituting the insulating layer to be secured to each other only with a limited level of reliability. The reason therefor is that parts of the insulating layer and the cooler secured to each other is subjected to application of high stress as the insulating plate made of ceramic is smaller in coefficient of linear expansion and higher in Young's modulus than the cooler made of metal.

A semiconductor device is subjected to change in temperature cycle due to change in temperature of an environment in which the semiconductor device is used, or due to heat generation in a semiconductor element of the semiconductor device itself. So, part of the insulating plate secured to the cooler that is considerably different in coefficient of linear expansion than the insulating plate is subjected to repeated application of thermal stress of large amplitude. Thus, a crack due to thermal stress may be generated, or thermal resistance may be increased as a result of development of the crack, leading to degeneration of the heat dissipation characteristics of a heat dissipating element. In addition, if the cooler is made of a composite material including metal, carbon and the like, a difference in coefficient of linear expansion between the cooler and the insulating plate made of ceramic is made smaller. However, such a composite material is very costly.

In the semiconductor device disclosed in patent literature 2, the cooler and the circuit part are hot pressed while an insulating sheet is interposed between a surface of the cooler and the circuit part to isolate the cooler and the circuit part. In this case, the aforementioned insulating plate made of ceramic is not used, thereby reducing thermal stress to be applied between the insulating plate and the cooler. However, it is difficult to press a large number of stacked coolers each having a surface with irregularities to which the insulating sheet is stuck, resulting in poor productivity during hot pressing.

### SUMMARY OF THE INVENTION

The present invention has been made in view of the aforementioned problems. It is an object of the present invention to provide a semiconductor device and a method of manufacturing the same capable of reliably responding to temperature change while achieving satisfactory productivity at low cost.

A semiconductor device of the present invention includes a cooler, a joined layer, an insulating layer, a metal layer, and a semiconductor element. The cooler has a main surface constructed of a metal base. The joined layer is fixed on the metal base through a joining layer. The insulating layer is fixed on the joined layer and which contains an organic resin as a base material. The metal layer is provided on the insulating layer. The semiconductor element is provided on the metal layer. A stacked structure with the joined layer, the insulating layer, and the metal layer is divided into parts containing one or a plurality of the semiconductor elements, and is fixed through the joining layer on the metal base.

The joined layer is fixed on the metal base through the joining layer. The insulating layer is fixed on the joined layer and which contains an organic resin as a base material. So, a distortion generated in the joining layer is not serious even if the semiconductor device is used while being subjected to repeated temperature change, thereby providing a high level of reliability to the semiconductor device. The stacked structure with the joined layer, the insulating layer, and the metal layer is divided into parts containing one or a plurality of the semiconductor elements, and is fixed through the joining layer on the metal base. This also suppresses a distortion to be generated in the joining layer.

A method of manufacturing a semiconductor device of the present invention includes the following steps (a) to (e). In the step (a), a cooler having a main surface constructed of a metal base is prepared. In the step (b), a metal layer and a joined layer are formed on the upper and lower surfaces respectively of an insulating layer containing an organic resin as a base material. The step (c) is performed after the step (b). In the step (c), the metal base is joined through a joining layer to the lower surface of the joined layer. The step (d) is performed after the step (b). In the step (d), the joining layer, the joined layer, the insulating layer, and the metal layer are divided. The step (e) is performed after the step (b). In the step (e), a semiconductor element is joined on the metal layer.

The method of manufacturing a semiconductor device of the present invention includes the steps (b) and (c) performed after the step (h). In the step (b), the metal layer and the joined layer are formed on the upper and lower surfaces respectively of the insulating layer containing an organic resin as a base material. In the step (c), the metal base is joined through the joining layer to the lower surface of the joined layer. So, a distortion generated in the joining layer is not serious even if the semiconductor device is used while being subjected to repeated temperature change, thereby providing a high level of reliability to the semiconductor device. The method further includes the step (d) performed after the step (b). In the step (d), the joining layer, the joined layer, the insulating layer, and the metal layer are divided. The provision of the step (d) further suppresses a distortion to be generated in the joining layer.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing the structure of a semiconductor device of the present invention;

FIGS. 2A and 2B are sectional views for comparison between the semiconductor device of the present invention and a conventional semiconductor device;

FIGS. 3 and 4 are sectional views each showing the structure of the semiconductor device of the present invention; and

FIGS. 5 to 8 are sectional views showing the steps of manufacturing the semiconductor device of the present invention.

### EMBODIMENT FOR CARRYING OUT THE INVENTION

### First Preferred Embodiment

### Structure

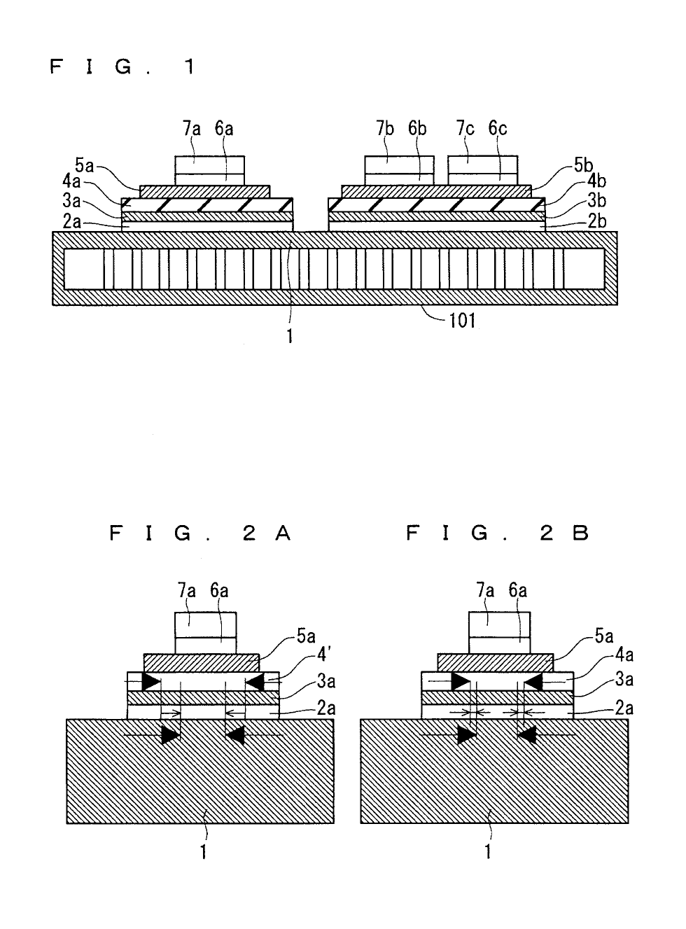

FIG. 1 is a sectional view of the structure of a semiconductor device of a first preferred embodiment. The semiconductor device of the first preferred embodiment includes a cooler 101 with a metal base 1 constituting one main surface of the cooler 101 and functioning as a top plate, and a joined layer 3a secured to the metal base 1 through a joining layer 2a. The joined layer 3a and an insulating layer 4a formed on the joined layer 3a are formed integrally with each other for example by film coating, pressing, or adhesive bonding. A metal layer 5a is formed on the insulating layer 4a. A semiconductor element 7a is formed over the metal layer 5a through a joining layer 6a.

That is, the joining layer 2a, the joined layer 3a, the insulating layer 4a, the metal layer 5a, the joining layer 6a, and the semiconductor element 7a are provided in this order over the metal base 1 into a stacked structure, and a plurality of stacked structures is formed on the metal base 1. To be specific, a joining layer 2b, a joined layer 3b, an insulating layer 4b, and a metal layer 5b are also stacked on the metal base 1. Further, a semiconductor element 7b is formed over the metal layer 5b through a joining layer 6b, and a semiconductor element 7c is formed over the metal layer 5b through a joining layer 6c. Namely, a stacked structure with a joined layer, an insulating layer, and a metal layer is divided into parts containing one or a plurality of semiconductor elements, and is fixed through a joining layer on the metal base 1.

The stacked structure is described as being formed on the metal base 1. Meanwhile, a cooler is not always placed vertically below a semiconductor element, but it may be placed in various positions. As an example, the cooler may be placed in a horizontal position, or may be placed upside down. So, the position of the stacked structure over the metal base 1 is determined in order to facilitate the understanding of FIG. 1.

The joining layers 6a, 6b and 6c are made of a metallic material of high heat conductivity such as solder, or a resin material containing a filler for better heat conductivity so that the joining layers 6a, 6b and 6c can dissipate heat generated in the semiconductor elements 7a, 7b and 7c satisfactorily. Or, if the heat conductivity of the joining layers 6a, 6b and 6c can be relatively low, the joining layers 6a, 6b and 6c may be made of an adhesive material containing an organic material.

The semiconductor device of the first preferred embodiment does not include an insulating layer stuck on a surface with irregularities of a cooler, but it includes stacked structures with the joining layer 2a and the insulating layer 4a, and the joining layer 2b and the insulating layer 4b that are joined to a metal base. So, the semiconductor device of the first preferred embodiment does not reduce productivity during hot pressing.

The joining layers 2a and 2b join the insulating layers 4a and 4b to the metal base 1 together with the joined layers 3a and 3b respectively. So, the joining layers 2a and 2b are preferably made of an adhesive material containing an organic component as a base material, or a metallic material containing solder as a base material. The joining layers 2a and 2b are more preferably made of a metallic material of excellent heat conductivity for better heat dissipation of the element. As an example, a solder material containing Sn as one of the base materials is used preferably.

For the same purpose, the joined layers 3a and 3b are also preferably made of a metallic material.

The effect of the semiconductor device of the first preferred embodiment achieved by using an organic resin to form the insulating layers 4a and 4b is described next by referring to FIG. 2. FIG. 2A is a sectional view of a semiconductor device including a stacked structure with the joining layer 2a, the joined layer 3a, an insulating layer 4′, the metal layer 5a, the joining layer 6a, and the semiconductor element 7a that are stacked on the metal base 1. The insulating layer 4′ contains ceramic as a base material, and which is different in Young's modulus and coefficient of linear expansion from the metal base 1 containing a conductive base material such as aluminum and copper. So, if this semiconductor device is used while being subjected to repeated temperature change, the insulating layer 4′ and the metal base 1 shrink to different degrees due to varying temperatures, generating a distortion in the joining layer 2a interposed between the insulating layer 4′ and the metal base 1. A crack may be generated and the generated crack may develop in the joining layer 2a if this distortion is generated repeatedly, resulting in a fear of degradation of heat conductivity.

In contrast, the insulating layer formed in the first preferred embodiment contains an organic resin as a base material, and a filler such as silica to enhance heat conductivity. Examples of the organic resin include epoxy resins, silicone resins, and acrylic resins. The insulating layer containing the organic resin as a base material is softer than an insulating material containing ceramic as a base material. So, a distortion generated in the joining layer 2a is less serious as shown in FIG. 2B even if the semiconductor device is used while being subjected to repeated temperature change. This means that use of an organic resin as a base material of the insulating layer 4a allows manufacture of the semiconductor device with a cooler having a high level of reliability inside.

Further, in the first preferred embodiment, the joined layers 3a and 3b, the insulating layers 4a and 4b, and the joining layers 2a and 2b are divided into parts containing one or a plurality of semiconductor elements, and are joined to the metal base 1 through the joining layers 2a and 2b as shown in FIG. 1. This further suppresses a distortion to be generated in the joining layers 2a and 2b by different degrees of shrinkage between the insulating layer 4a, 4b made of an organic resin and the metal base 1, thereby suppressing the development of a crack.

The insulating layers 4a and 4b separated from each other may have respective functions to form a circuit of the semiconductor device of the first preferred embodiment. As an example, a stacked structure (circuit structure) containing the semiconductor element 7a forms a three-phase bridge circuit of a main circuit, whereas a stacked structure containing the semiconductor element 7b forms a voltage-boosting converter.

Separation into circuit structures having respective functions allows formation of a large number of circuit structures including a bridge circuit and a voltage booster circuit. A large number of circuit structures formed as small units are assembled together to effectively manufacture a semiconductor device. This way of manufacture achieves high efficiency and has a high industrial value as only those circuits that operate well are selected and then assembled.

Circuit structures are interconnected if necessary through a metal wire, a metal plate, or a substrate (not shown), for example.

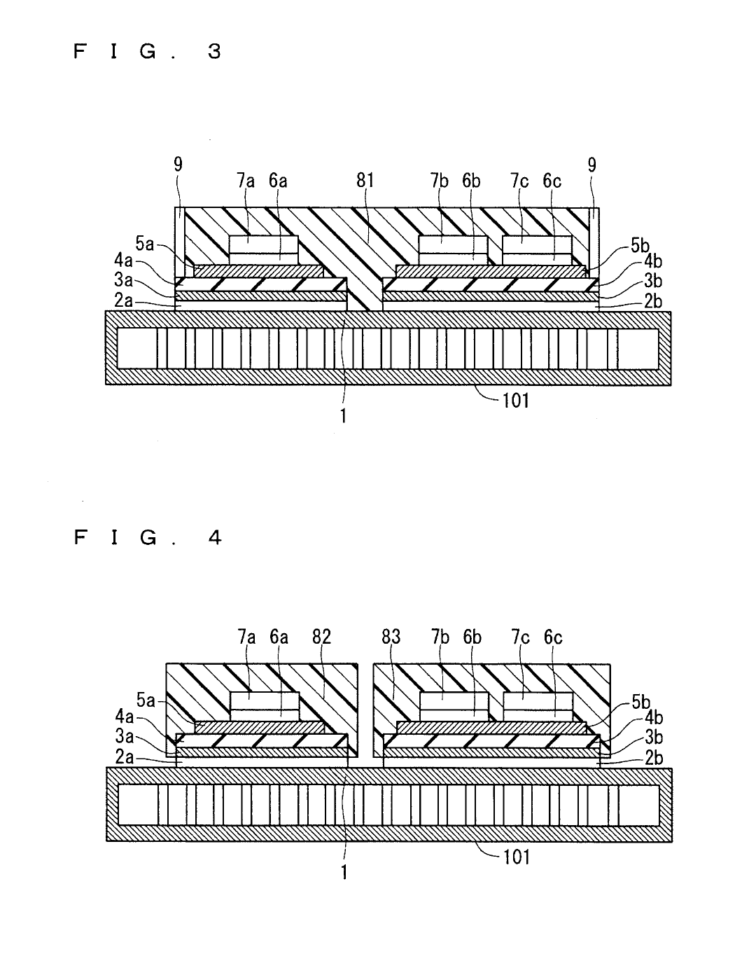

As shown in FIG. 3, the insulating layers 4a and 4b, the metal layers 5a and 5b, the joining layers 6a, 6b and 6c, and the semiconductor elements 7a, 7b and 7c may be sealed with a sealing resin 81. A section requiring filling with the sealing resin 81 may be filled with the sealing resin 81 in an appropriate amount by pouring the sealing resin 81 into a case 9 extending vertically from end portions of the insulating layers 4a and 4b. Here, the provision of the case 9 is arbitrarily determined.

The metal layers 5a and 5b separated between elements or separated on the same metal base 1 may have different potentials depending on the circuit formation. An insulation distance should be maintained between the metal layers 5a and 5b according to circuit specifications if the metal layers 5a and 5b have different potentials. In this regard, provision of the sealing resin 81 shown in FIG. 3 makes the insulation distance longer than that of the case where the metal layers 5a and 5b are exposed, thereby allowing size reduction of the semiconductor device.

The insulating layers 4a and 4b contain an organic resin as a base material as already described. So, the insulating layers 4a, 4b and the sealing resin 81 adhesively contact with each other firmly if the sealing resin 81 also contains an organic resin such as a silicone-based resin or an epoxy-based resin, thereby achieving compact size and excellent insulation of the semiconductor device.

The stacked structures separated from each other may be sealed separately with resins as shown in FIG. 4. To be specific, the stacked structure with the joined layer 3a, the insulating layer 4a, the metal layer 5a, the joining layer 6a, and the semiconductor element 7a is sealed with a sealing resin 82. Further, the stacked structure (circuit structure) with the joined layer 3b, the insulating layer 4b, the metal layer 5b, the joining layers 6b and 6c, and the semiconductor elements 7b and 7c is sealed with a sealing resin 83. Small circuit units are each sealed with corresponding sealing resins, and are placed on the base plate 1 of the cooler 101 in units of sealing resins. As for interconnection between the circuit structures, interconnecting members connected to the semiconductor elements or to the metal layers inside the sealing resins are given terminals that project outward of predetermined surfaces of the corresponding sealing resins, and these terminals are joined together to interconnect the circuit structures. The circuit structures can be held securely if the sealing resins 82 and 83 are made of a resin material containing epoxy as a base material, for example. This makes handling considerably easy to enhance manufacturing efficiency.

The circuit structures are held securely with the corresponding sealing resins 82 and 83, so it is not necessary to prepare a container such as a case outside each of the circuit structures to house the circuit structure. A member such as a terminal table for making connection between the outside of the semiconductor device and the interconnecting lines may be prepared, if necessary.

The effect of the semiconductor device of the first preferred embodiment becomes more remarkable with the greater amplitude of temperature change. So, not only silicon but also a wide band gap semiconductor wider in band gap than silicon may be employed as a material of the semiconductor elements 7a, 7b and 7c. Examples of the wide band gap semiconductor include silicon carbide, gallium nitride based materials, and diamond. Development of a crack in the joining layer is still suppressed if the semiconductor elements 7a, 7b and 7c made of a wide band gap semiconductor are operated in higher temperature than that in which a normal semiconductor element is operated, thereby providing a higher level of reliability to the semiconductor device.

### Manufacturing Steps

Steps of manufacturing the semiconductor device of the first preferred embodiment are described by referring to FIGS. 5 to 8.

First, a joined layer 3 and a metal layer 5 are respectively placed on the lower and upper surfaces of an insulating layer 4 containing an organic resin as a base material. Then, the joined layer 3 and the metal layer 5 are joined to the insulating layer 4, and the insulating layer 4 is cured by hot pressing (FIG. 5). The joined layer 3 is made for example of metal.

The insulating layer 4 in the form of a plate may be interposed between the joined layer 3 and the metal layer 5. Or, a film of the insulating layer 4 may be applied in advance to the lower surface of the metal layer 5 or to the upper surface of the joined layer 3, and then may be solidified by hot pressing.

The application of a film of the insulating layer 4 and hot pressing thereof are such that the film of the insulating layer 4 is applied to one of the joined layer 3 and the metal layer 5 and then hot pressed. Next, the other one of the joined layer 3 and the metal layer 5 is placed on the insulating layer 4 and then hot pressing is conducted again. As a result, the joined layer 3, the insulating layer 4, and the metal layer 5 are united into one securely, while the insulating layer 4 is allowed to have a predetermined thickness.

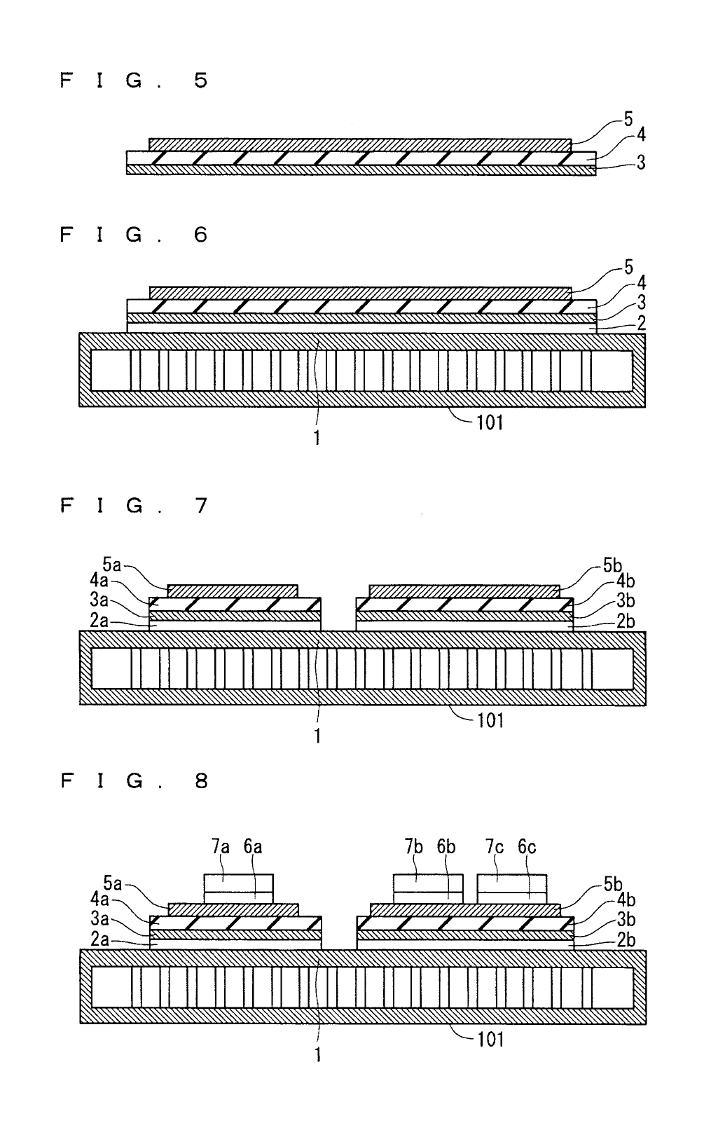

Next, the metal base 1 of the cooler 101 is joined to the lower surface of the joined layer 3 through the joining layer 2 (FIG. 6). The metal base 1 is combined after the insulating layer 4, the joined layer 3, and the metal layer 5 are united into one. This makes handling of the insulating layer 4 easy containing an organic resin that is hard to handle as it might be damaged for its low strength despite its softness.

The semiconductor device of the first preferred embodiment does not include an insulating layer stuck on a surface with irregularities of a cooler, but it includes a stacked structure with the joining layer 2 and the insulating layer 4 that is joined to the metal base 1. So, productivity is not reduced during hot pressing

Next, the joining layer 2, the joined layer 3, the insulating layer 4, and the metal layer 5 formed on the metal base 1 are divided into predetermined regions (FIG. 7) for example by chemical means such as etching, or by mechanical means such as cutting with a blade. As a result, the joining layer 2, the joined layer 3, the insulating layer 4, and the metal layer 5 are divided into a stacked structure with the joining layer 2a, the joined layer 3a, the insulating layer 4a, and the metal layer 5a, and a stacked structure with the joining layer 2b, the joined layer 3b, the insulating layer 4b, and the metal layer 5b.

Then, the semiconductor element 7a is joined to the metal layer 5a through the joining layer 6a, the semiconductor element 7b is joined to the metal layer 5b through the joining layer 6b, and the semiconductor element 7c is joined to the metal layer 5b through the joining layer 6c (FIG. 8).

While the semiconductor elements 7a, 7b and 7c are shown to be placed on the metal layers 5a and 5b after separation into the stacked structures. Meanwhile, separation into the stacked structures may be made after the semiconductor elements 7a, 7b and 7c are placed on the metal layers 5a and 5b. In addition, fixation to the base plate 1 (FIG. 6), separation into the stacked structures (FIG. 7), and fixation of the semiconductor elements to the metal layers (FIG. 8) may be performed in a different order to the extent practical.

If the sealing resin 81 is to be provided as shown in FIG. 3, the sealing resin 81 is poured after the metal layer 5 and the joined layer 3 are joined to the upper and lower surfaces of the insulating layer 4 respectively, and after the semiconductor element 7 is placed on the metal layer 5 through the joining layer 6. Then, the joined layers 3a and 3b, the insulating layers 4a and 4b, the metal layers 5a and 5b, and the semiconductor elements 7a, 7b and 7c are sealed with the sealing resin. The metal base 1 is thereafter joined to the lower surface of the joined layer 3 through the joining layer 2. In this case, separation into the stacked structures may be made at any time.

Each member sealed with the sealing resin 81 is held securely while being joined to the metal base 1, so that it can be joined tightly to the metal base 1.

### Effects

The semiconductor device of the first preferred embodiment includes the cooler 101 having a main surface constructed of the metal base 1, the joined layers 3a and 3b fixed on the metal base 1 through the joining layers 2a and 2b, the insulating layers 4a and 4b fixed on the joined layers 3a and 3b and which contain an organic resin as a base material, the metal layers 5a and 5b provided on the insulating layers 4a and 4b, and the semiconductor elements 7a, 7b and 7c provided on the metal layers 5a and 5b. A stacked structure with the joined layers 3a and 3b, the insulating layers 4a and 4b, and the metal layers 5a and 5b is divided into parts containing one or the plurality of semiconductor elements 7a, 7b and 7c, and is fixed through the joining layers 2a and 2b on the metal base 1. So, a distortion generated in the joining layer 2a is suppressed even if the semiconductor device is used while being subjected to repeated temperature change, thereby providing a high level of reliability to the semiconductor device.

The joined layers 3a and 3b are made of metal. So, the metal base plate 1 and the insulating layers 4a, 4b are joined through a material of high heat conductivity, thereby enhancing the heat dissipation characteristics of the cooler 101.

The joined layers 3a and 3b, the insulating layers 4a and 4b, the metal layers 5a and 5b, and the semiconductor elements 7a, 7b and 7c are sealed with the sealing resin 81. This increases an insulation distance between the metal layers 5a and 5b, thereby contributing to the size reduction of the semiconductor device.

The semiconductor elements 7a, 7b and 7c may be made of a wide band gap semiconductor. In this case, the semiconductor device of the first preferred embodiment still achieves a high level of reliability if the semiconductor elements 7a, 7b and 7c are operated in high temperature.

A method of manufacturing a semiconductor device of the first preferred embodiment includes the following steps (a) to (e). In the step (a), the cooler 101 having a main surface constructed of the metal base 1 is prepared. In the step (b), the metal layer 5 and the joined layer 3 are formed on the upper and lower surfaces respectively of the insulating layer 4 containing an organic resin as a base material. The step (c) is performed after the step (b). In the step (c), the metal base 1 is joined through the joining layer 2 to the lower surface of the joined layer 3. The step (d) is performed after the step (b). In the step (d), the joining layer 2, the joined layer 3, the insulating layer 4, and the metal layer 5 are divided. The step (e) is performed after the step (b). In the step (e), the semiconductor elements 7a, 7b and 7c are joined to the metal layer 5. So, a distortion generated in the joining layer 2a is suppressed even if the semiconductor device is used while being subjected to repeated temperature change, thereby providing a high level of reliability to the semiconductor device.

The joined layer formed in the step (b) is made of metal. So, the metal base plate 1 and the insulating layers 4a, 4b are joined through a material of high heat conductivity, thereby enhancing the heat dissipation characteristics of the cooler 101.

The method of manufacturing a semiconductor device of the first preferred embodiment further includes the step (f) performed between the steps (e) and (c). In the step (f), the joined layers 3a and 3b, the insulating layers 4a and 4b, the metal layers 5a and 5b, and the semiconductor elements 7a, 7b and 7c are sealed with a sealing resin. This increases an insulation distance between the metal layers 5a and 5b, thereby contributing to the size reduction of the semiconductor device.

The semiconductor elements 7a, 7b and 7c joined to the metal layer 5 in the step (e) may be made of a wide band gap semiconductor. In this case, operating the semiconductor elements 7a, 7b and 7c in high temperature still achieves reliability at a high level.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a cooler having a main surface constructed of a metal base;
a joined layer fixed on said metal base through a joining layer;
an insulating layer fixed on said joined layer and which contains an organic resin as a base material;
a metal layer provided on said insulating layer; and
a semiconductor element provided on said metal layer,
wherein a stacked structure with said joined layer, said insulating layer, and said metal layer is divided into parts containing one or a plurality of said semiconductor elements, and is fixed through said joining layer on said metal base.

2. The semiconductor device according to claim 1, wherein said joined layer is made of metal.

3. The semiconductor device according to claim 1, wherein said joined layer, said insulating layer, said metal layer, and said semiconductor element are sealed with a sealing resin.

4. The semiconductor device according to claim 1, wherein said semiconductor element is made of a wide band gap semiconductor.

5. A method of manufacturing a semiconductor device, comprising the steps of:
(a) preparing a cooler having a main surface constructed of a metal base;
(b) forming a metal layer and a joined layer on the upper and lower surfaces respectively of an insulating layer containing an organic resin as a base material;
(c) joining said metal base through a joining layer to the lower surface of said joined layer, said step (c) being performed after said step (b);
(d) dividing said joining layer, said joined layer, said insulating layer, and said metal layer, said step (d) being performed after said step (b); and
(e) joining a semiconductor element on said metal layer, said step (e) being performed after said step (b).

6. The method according to claim 5, wherein said joined layer formed in said step (b) is made of metal.

7. The method according to claim 5, further comprising the step of:
(f) sealing said joined layer, said insulating layer, said metal layer, and said semiconductor element with a sealing resin, said step (f) being performed between said steps (e) and (c).

8. The method according to claim 5, wherein said semiconductor element joined to said metal layer in the step (e) is made of a wide band gap semiconductor.
